(19) United States
(12) Patent Application Publication
(10) Pub. No.: US 2026/0136808 A1
(43) Pub. Date: May 14, 2026

(54) DISPLAY APPARATUS

(71) Applicant: LG DISPLAY CO., LTD., SEOUL (KR)

(72) Inventor: SungSik Son, Daegu (KR)

(21) Appl. No.: 19/194,376

(22) Filed: Apr. 30, 2025

(30) Foreign Application Priority Data
Nov. 12, 2024 (KR) 10-2024-0160545

(51) Int. Cl. H10K 59/80; G02B 5/20; H10K 59/95

(52) U.S. Cl. CPC H10K 59/873; H10K 59/95; G02B 5/208

(57) ABSTRACT

A display apparatus includes a display panel including a display portion and a non-display portion, a chip on film (COF) film connected to the non-display portion, a printed circuit board connected to the non-display portion through the COF film, a cover glass positioned on the display panel and including a step portion on at least a portion of an upper surface of the cover glass, and a protective film covering a lower portion and a side surface of the display panel.

### CROSS-REFERENCE TO RELATED APPLICATIONS

Pursuant to 35 U.S.C. § 119(a), this application claims the benefit of an earlier filing date and right of priority to Korean Patent Application No. 10-2024-0160545 filed on Nov. 12, 2024 in the Korean Intellectual Property Office, the disclosure of which is incorporated herein by reference in its entirety.

### TECHNICAL FIELD

The present disclosure relates to a display apparatus.

### BACKGROUND

As the information society develops, the various demands for display apparatuses that display images are increasing. Accordingly, various types of display apparatuses such as a liquid crystal display apparatus and an organic light emitting diode display apparatus are being utilized.

Among display apparatuses, the organic light-emitting diode display apparatus is self-luminous, has superior viewing angles and contrast ratios compared to the liquid crystal display apparatus, does not require a separate backlight, allowing for lightweight and thin designs, and has the advantage of low power consumption. In addition, the organic light-emitting diode display apparatuses have the advantage of being able to operate at low voltage, a fast response speed, and low manufacturing costs.

Recently, a display apparatus has been developed to be thin and light while providing high performance, so that the display apparatus can be carried and moved by users or installed in moving devices such as vehicles. Through this, the display apparatus is being developed so that users can utilize the display apparatus more conveniently.

### SUMMARY

The present disclosure provides a display apparatus including: a display panel including a display portion and a non-display portion; a chip on film (COF) film connected to the non-display portion; a printed circuit board connected to the non-display portion through the COF film; a cover glass positioned on the display panel and including a step portion on at least a portion of an upper surface of the cover glass; and a protective film covering a lower portion and a side surface of the display panel, in which the protective film has a UV blocking function.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view illustrating a display apparatus according to one example implementation of the present disclosure;

FIG. 2 is a schematic block diagram of the display apparatus according to one example implementation of the present disclosure;

FIG. 3 is a circuit diagram illustrating a circuit configuration of a sub-pixel according to one example implementation of the present disclosure;

FIG. 4 is a cross-sectional view illustrating the sub-pixel of the display apparatus according to one example implementation of the present disclosure;

FIG. 5 is a cross-sectional view of the display apparatus according to one example implementation of the present disclosure;

FIG. 6 is an exploded perspective view of the display apparatus according to one example implementation of the present disclosure;

FIG. 7 is an enlarged view of an area A of FIG. 6;

FIG. 8 is an exploded perspective view of a display apparatus according to another example implementation of the present disclosure;

FIG. 9 is a rear perspective view of the display apparatus according to another example implementation of the present disclosure;

FIG. 10 is an enlarged view of an area B of FIG. 9;

FIG. 11 is an enlarged view of an area C of FIG. 9;

FIG. 12 is a rear perspective view of the display apparatus according to another example implementation of the present disclosure; and

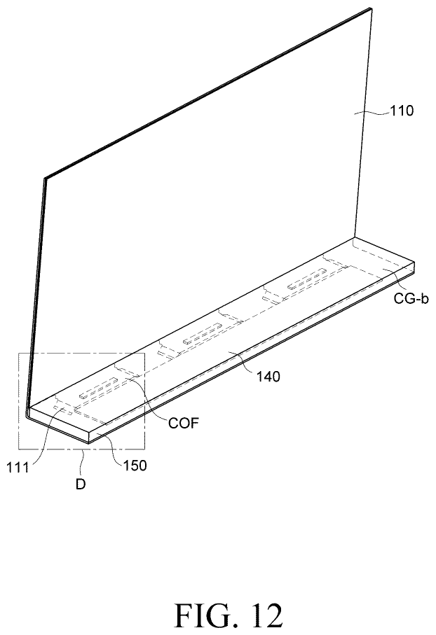

FIG. 13 is an enlarged view of an area D of FIG. 12.

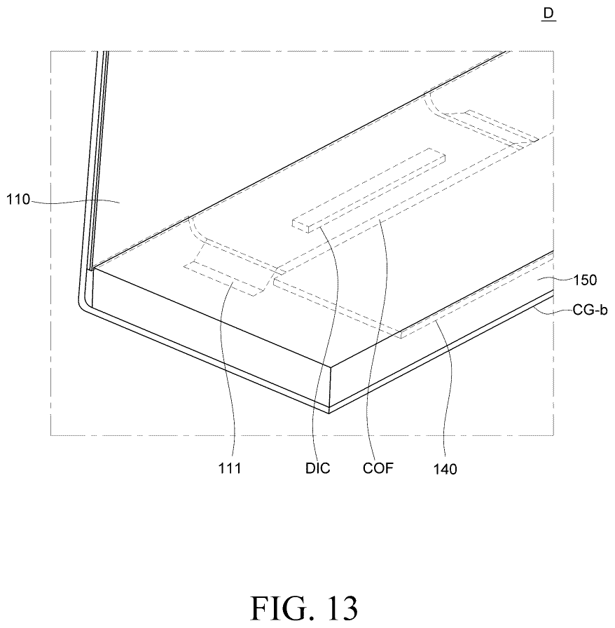

### DETAILED DESCRIPTION

An object of the present disclosure is to provide a display apparatus capable of ensuring high reliability in a vehicle environment by providing a structure effective for blocking UV rays in all directions.

In addition, an object of the present disclosure provides a transparent display apparatus that displays an image while allowing the rear side to be seen through.

In addition, the present disclosure provides a display apparatus that improves quality by suppressing damage such as external cracks by proposing a finishing structure using a protective film that surrounds a periphery of the display apparatus.

In addition, the present disclosure provides a display apparatus having a sturdy fastening structure and a slim design by providing a protective film that protects an extended cover glass and a COF film and a cover portion that surrounds the same.

According to the display apparatus according to one example implementation of the present disclosure, the cover glass includes a step portion on at least a portion of the upper surface of the cover glass, and the protective film positioned on the step portion is disposed to cover the lower portion and the side surface of a display panel. Therefore, it is possible to protect the display panel from cracks or the like that may occur from the outside, thereby improving quality and having high reliability.

In addition, the protective film includes a UV blocking function, thereby protecting the display panel from quality degradation caused by UV light, which is likely to occur particularly in a vehicle environment, thereby improving reliability.

The display apparatus according to one example implementation of the present disclosure provides a transparent display apparatus that displays an image while allowing the rear side to be seen through, while having a structure that is light in weight and slim in thickness, thereby making installation in a vehicle easier.

In addition, by providing the protective film that protects the extended cover glass and the COF film and a cover portion surrounding them, the display apparatus having a sturdy fastening structure and a stable design can be implemented.

Therefore, the display apparatus according to the example implementation of the present disclosure can maximize ESG effect through improving the quality of the display apparatus and reducing material costs.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

When the relation of a time sequential order is described using the terms such as “after”, “continuously to”, “next to”, and “before”, the order may not be continuous unless the terms are used with the term “immediately” or “directly”.

In describing components of the example implementation of the present disclosure, terminologies such as first, second, A, B, (a), (b), and the like may be used. These terminologies are used to distinguish a component from the other component, but a nature, an order, or the number of the components is not limited by the terminology. When a component is “linked”, “coupled”, or “connected” to another component, the component may be directly linked or connected to the other component. However, unless specifically stated otherwise, it should be understood that a third component may be interposed between the components which may be indirectly linked or connected.

It should be understood that “at least one” includes all combinations of one or more of associated components. For example, “at least one of first, second, and third components” means that not only a first, second, or third component, but also all combinations of two or more of first, second, and third components are included.

In the present disclosure, a “display apparatus” may include a display apparatus which includes a display panel and a driver for driving the display panel, in a narrow sense, such as a liquid crystal module (LCM), an organic light emitting module (OLED module), and a quantum dot module. Further, the “display apparatus” may further include a set electronic apparatus or a set apparatus (or a set device) which is a complete product or a final product including an LCM, an OLED module, a QD module, etc., such as a notebook computer, a television, or a computer monitor, an automotive display apparatus or equipment display apparatus including another type of vehicle and a mobile electronic apparatus including a smart phone or an electronic pad.

Accordingly, the display apparatus of the present disclosure may include not only a display apparatus itself in a narrow sense such as an LCM, an OLED module, a QD module, etc., but also an applied product or a set apparatus which is a final consumer device including the LCD, the OLED module, the QD module, etc.

Further, in some cases, the LCM, the OLED module, or the QD module which is configured by a display panel and a driver may be represented as “a display apparatus” in a narrow sense and an electronic device as a complete product including the LCM, the OLED module, and the QD module may be represented as a “set apparatus”. For example, the display apparatus in the narrow sense includes a liquid crystal (LCD) display panel, an OLED display panel, or a quantum dot display panel and a source PCB which is a controller for driving the display panel. In contrast, the set apparatus may be a concept further including a set PCB which is a set controller which is electrically connected to the source PCB to control the entire set apparatus.

As a display panel used in the example implementation of the present disclosure, any type of display panel such as a liquid crystal display panel, an organic light emitting diode (OLED) display panel, a quantum dot (QD) display panel, and an electroluminescent display panel may be used. The display panel of the present example implementation is not limited to a specific display panel in which a bezel is bent with a flexible substrate for the organic light emitting diode (OLED) display panel and a back plate support structure therebelow. Further, a display panel used for the display apparatus according to the example implementation of the present disclosure is not limited to a shape or a size of the display panel.

For example, when the display panel is an OLED display panel, the display panel may include a plurality of gate lines, data lines, and pixels formed at intersecting areas of the gate lines and/or data lines. Further, the display panel may be configured to include an array including a thin film transistor which is an element to selectively apply a voltage to each pixel, a light emitting diode layer on the array, an encapsulation substrate or an encapsulation layer, and the like disposed on the array so as to cover the light emitting diode layer. The encapsulation layer may protect the thin film transistor the light emitting diode layer, and the like from external impacts and may suppress the permeation of moisture or oxygen into the light emitting diode layer. Further, a layer formed on the array may include an inorganic light emitting layer, for example, a nano-sized material layer quantum dots, or the like.

The features of various example implementations of the present disclosure can be partially or entirely coupled to or combined with each other and can be interlocked and operated in technically various ways, and the example implementations can be carried out independently of or in association with each other.

Hereinafter, the example implementation of the present disclosure will be described with reference to the accompanying drawings and example implementations as follows. Scales of components illustrated in the accompanying drawings are different from the real scales for the purpose of description, so that the scales are not limited to those illustrated in the drawings.

Hereinafter, an example implementation of the present disclosure will be described in detail with reference to the drawings.

Hereinafter, example implementations will be described with reference to the drawings. In the present disclosure, when a component (or area, layer, portion, or the like) is said to be “on”, “connected”, or “coupled” to another component, it means that the component may be directly connected/coupled to another component, or a third component may be disposed between them.

Identical drawing reference numerals refer to identical components. Also, in the drawings, the thicknesses, proportions, and dimensions of the components are exaggerated for the purpose of effectively explaining the technical contents. “And/or” includes all combinations of one or more that the associated components can define.

The terms first, second, or the like may be used to describe various components, but the components are not limited by the terms. The terms are only used to distinguish one component from another. For example, without departing from the scope of the present example implementations, the first component may be referred to as the second component, and similarly, the second component may also be referred to as the first component. The singular expression includes the plural expression unless the context clearly indicates otherwise.

The terms “below”, “under”, “above,” and “on” or the like are used to describe the relationships between components depicted in the drawings. The above terms are relative concepts and are described based on the directions indicated in the drawings.

It should be understood that the terms “include” or “have” are intended to specify the presence of a feature, number, step, operation, component, part, or combination thereof described in the disclosure, but do not exclude in advance the possibility of the presence or addition of one or more other features, numbers, steps, operations, components, parts, or combinations thereof.

Hereinafter, an example implementation of the present disclosure will be described with reference to the attached drawings.

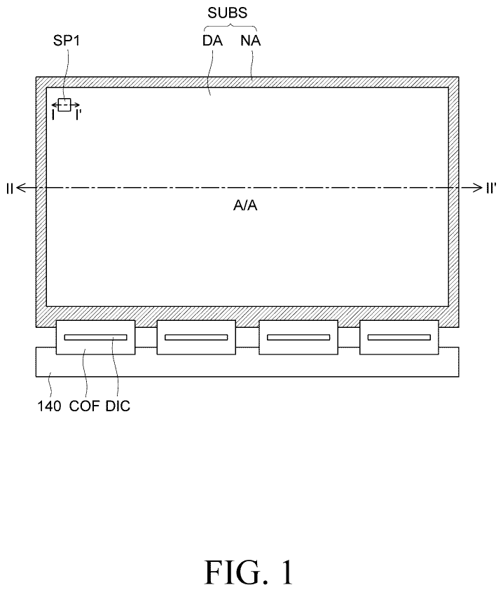

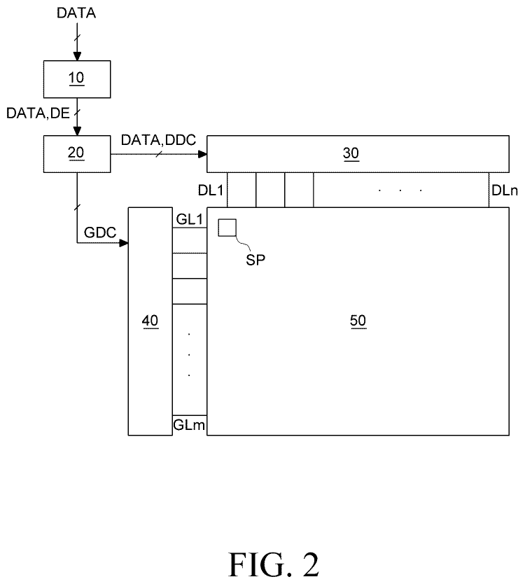

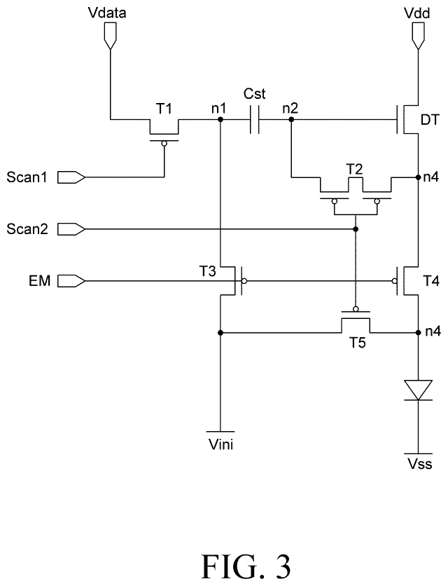

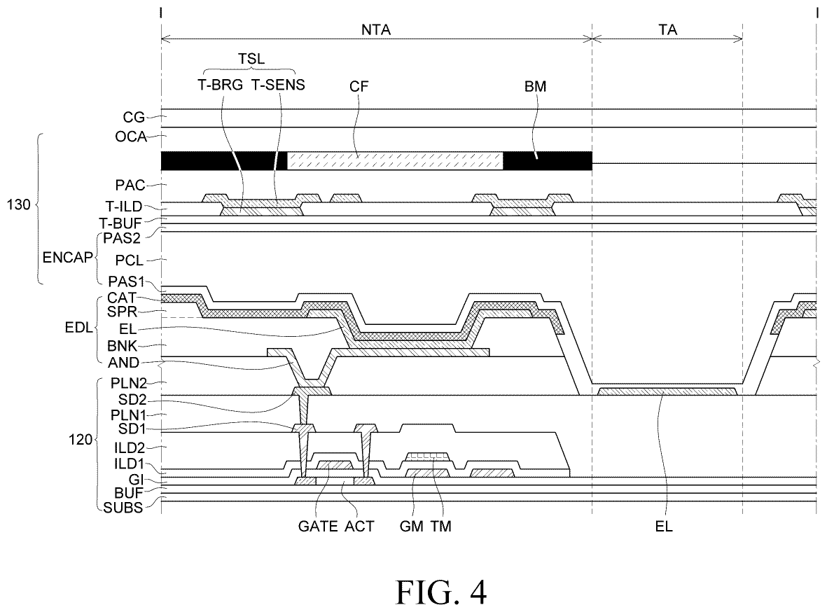

FIG. 1 is a plan view illustrating a display apparatus according to one example implementation of the present disclosure. FIG. 2 is a schematic block diagram of the display apparatus according to one example implementation of the present disclosure. FIG. 3 is a circuit diagram illustrating a circuit configuration of a sub-pixel according to one example implementation of the present disclosure. FIG. 4 is a cross-sectional view illustrating the sub-pixel of the display apparatus according to one example implementation of the present disclosure.

Referring to FIG. 1, the display apparatus of the present disclosure may include a substrate SUBS, and the substrate SUBS may include a display area DA and a non-display area NA. In addition, the substrate SUBS may be made of glass or plastic material. In the case of the substrate SUBS made of plastic material, the substrate may be manufactured as a flexible substrate. In this case, the flexible substrate is a resin substrate having flexible characteristics, and may be made of the same or different materials.

The display area DA may be provided on the substrate SUBS, and the non-display area NA may be provided on the periphery of the display area DA. A pad portion may be provided on one side of the non-display area NA. For example, the pad portion may be provided on the lower side of the non-display area NA, but is not limited thereto. A COF film COF may be provided on the pad portion.

The display area DA includes a plurality of sub-pixels SP, and may emit red, green, and blue light, or may emit red, green, blue, and white light. A GIP driving unit (not illustrated) for applying a gate driving signal to the display area DA may be provided on one side of the display area DA. In addition, the COF film (Chip on Film) may be attached to the pad portion (not illustrated) provided on one side of the display area DA. For example, the GIP driving unit may be provided on the right side of the display area DA, and the pad portion may be provided on the lower side of the display area DA. Through the COF film, a data signal and power may be applied to a plurality of signal lines (not illustrated) provided in the display area DA.

Referring to FIG. 2, the display apparatus may include an image processing unit 10, a timing control unit 20, a data driving unit 30, a gate driving unit 40, and a display panel 50.

The image processing unit 10 may output a data signal DATA, a data enable signal DE, or the like supplied from the outside. In addition to the data enable signal DE, the image processing unit 10 may output various driving signals. For example, the image processing unit 10 may output one or more of a vertical synchronization signal, a horizontal synchronization signal, and a clock signal, but is not limited thereto. In addition, the image processing unit 10 may be formed in the form of an integrated circuit (IC) on a system circuit board.

The timing control unit 20 may receive the data signal DATA and the data enable signal DE from the image processing unit 10. In addition, the timing control unit 20 may receive various driving signals such as the vertical synchronization signal, the horizontal synchronization signal, and the clock signal.

The timing control unit 20 may output a gate timing control signal GDC and a data timing control signal DDC based on the driving signal. The gate timing control signal GDC may control the operation timing of the gate driving unit 40, and the data timing control signal DDC may control the operation timing of the data driving unit 30. In addition, the timing control unit 20 may be formed in an IC form on a control circuit board.

In response to the data timing control signal DDC supplied from the timing control unit 20, the data driving unit 30 may convert the data signal DATA supplied from the timing control unit 20 into a gamma reference voltage and output the converted voltage. In addition, the data driving unit 30 may output a data signal DATA through data lines DL1 to DLn. The data driving unit 30 may be attached in an IC form on a substrate SUBS.

In response to the gate timing control signal GDC supplied from the timing control unit 20, the gate driving unit 40 may output the gate signal while shifting the level of the gate voltage. In addition, the gate driving unit 40 may output the gate signal through gate lines GL1 to GLm. The gate driving unit 40 may be formed in an IC form on the gate circuit board or may be formed in a gate in panel (GIP) manner on the display panel 50.

The display panel 50 may display an image in response to the data signal DATA and the gate signal supplied from the data driving unit 30 and the gate driving unit 40. In addition, the display panel 50 may include the sub-pixels SP that display an image.

Referring to FIG. 3, the pixel circuit includes an OLED element (OLED), a first TFT T1, a second TFT T2, a third TFT T3, a fourth TFT T4, a fifth TFT T5, a driving TFT DT, and a storage capacitor Cst (6T1C).

The first and second electrodes of the first TFT T1 are respectively connected to a data line Vdata and a first node n1, and the gate electrode is connected to a first scan line Scan1. That is, the first TFT T1 is turned on or off according to a first scan signal Scan1 applied through the first scan line, and when turned on, supplies a data voltage Vdata of the data line to the first node n1.

The first and second electrodes of the second TFT T2 are respectively connected to a second node n2 and a third node n3, and the gate electrode is connected to the second scan line Scan2. That is, the second TFT T2 is turned on or off according to the second scan signal Scan2 applied through the second scan line, and connects the second node n2 and the third node n3 when turned on.

The first and second electrodes of the third TFT T3 are respectively connected to the first node n1 and a reference voltage supply line Vref, and the gate electrode is connected to an emission control signal supply line EM. That is, the third TFT T3 is turned on or off according to the emission control signal EM supplied by the emission control signal supply line, and when turned on, supplies the reference voltage Vref supplied by the reference voltage supply line to the first node n1.

The first and second electrodes of the fourth TFT T4 are respectively connected to the third node n3 and the fourth node n4, and the gate electrode is connected to the emission control signal supply line EM. That is, the fourth TFT T4 is turned on or off according to the emission control signal EM supplied by the emission control signal supply line, and connects the third node n3 and the fourth node n4 when turned on.

The first and second electrodes of the fifth TFT T5 are respectively connected to the reference voltage supply line Vref and the fourth node n4, and the gate electrode is connected to the second scan line Scan2. That is, the fifth TFT T5 is turned on or off according to the second scan signal Scan2 applied through the second scan line, and when turned on, supplies the reference voltage Vref supplied by the reference voltage supply line to the fourth node n4.

The first and second electrodes of the driving TFT DT are respectively connected to a high-potential voltage supply line Vdd and the third node n3, and the gate electrode is connected to the second node n2. That is, the driving TFT DT is turned on or off depending on the voltage of the second node n2, and when turned on, supplies the high-potential voltage Vdd supplied by the high-potential voltage supply line to the third node n3.

The storage capacitor Cst is connected between the first node n1 and the second node n2 to maintain the data voltage Vdata supplied through the first TFT T1 constant for one frame. That is, the storage capacitor Cst maintains a gate-source voltage Vgs of the driving TFT constant for one frame.

The anode electrode of the OLED element (OLED) is connected to the fourth node n4, and the cathode electrode is connected to a low-potential voltage supply line Vss.

Although FIG. 3 illustrates a 6T1C pixel circuit including six TFTs and one capacitor, the present disclosure is not limited thereto and may be applied to all pixel circuits utilizing the reference voltage Vref, including a 3T1C pixel circuit including three TFTs and one capacitor.

Referring to FIG. 4, the first display area DA may include a non-transparent area NTA and a transparent area TA.

First, referring to FIG. 4, the laminated structure of the non-transparent area NTA included in the first display area DA will be described.

Although not specified in the drawing, the substrate SUBS may be composed of multiple pieces and may include an interlayer insulating layer therebetween. Through this, moisture penetration may be suppressed. For example, a plurality of substrates SUBS may be polyimide (PI) substrates. The substrate according to an example implementation of the present disclosure is made of glass, but is not limited thereto.

A buffer layer BUF may be disposed on the substrate SUBS. The buffer layer BUF may also be composed of a plurality of multi-buffer layers.

An active layer ACT of a driving transistor may be disposed on the buffer layer BUF.

A gate insulating layer GI may be disposed to cover the active layer ACT.

A gate electrode GATE of the driving transistor may be disposed on the gate insulating layer GI. At this time, a gate material layer GM may be disposed on the gate insulating layer GI together with the gate electrode GATE of the driving transistor at a position different from the formation position of the driving transistor.

A first interlayer insulating layer ILD1 may be disposed to cover the gate electrode GATE and the gate material layer GM. A metal pattern TM may be disposed on the first interlayer insulating layer ILD1. A second interlayer insulating layer ILD2 may be disposed to cover the metal pattern TM on the first interlayer insulating layer ILD1.

Two first source-drain electrode patterns SD1 may be disposed on the second interlayer insulating layer ILD2. One of the two first source-drain electrode patterns SD1 is a source node of the driving transistor, and the other is a drain node of the driving transistor.

The two first source-drain electrode patterns SD1 may be connected to one side and the other side of the active layer ACT through contact holes of the second interlayer insulating layer ILD2, the first interlayer insulating layer ILD1, and the gate insulating layer GI. A portion of the active layer ACT overlapping the gate electrode GATE is a channel area. One of the two first source-drain electrode patterns SD1 is connected to one side of the channel area in the active layer ACT, and the other of the two first source-drain electrode patterns SD1 is connected to the other side of the channel area in the active layer ACT.

A first planarization layer PLN1 and a second planarization layer PLN2 may be disposed on the first source-drain electrode pattern SD1.

The first planarization layer PLN1 may be disposed on the first source-drain electrode pattern SD1. The second source-drain electrode pattern SD2 may be disposed on the first planarization layer PLN1. The second source-drain electrode pattern SD2 may be connected to one of the two first source-drain electrode patterns SD1 through the contact hole of the first planarization layer PLN1.

The second planarization layer PLN2 may be disposed to cover the second source-drain electrode pattern SD2. A light-emitting diode layer EDL may be positioned on the second planarization layer PLN2.

Next, the laminated structure of the light-emitting diode layer EDL will be described.

An anode electrode AND is disposed on the second planarization layer PLN2. The anode electrode AND is electrically connected to the second source-drain electrode pattern SD2 through the contact hole of the second planarization layer PLN2.

A bank BNK is disposed to cover the anode electrode AND. The bank BNK may have a portion open corresponding to the light-emitting area of the sub-pixel SP. A portion of the anode electrode AND may be exposed through the open portion of the bank BNK. The light-emitting layer EL may be disposed in and around the open portion of the bank BNK. Accordingly, the light-emitting layer EL may be disposed on the anode electrode AND exposed through the open portion of the bank BNK.

A common electrode CAT may be disposed on the light-emitting layer EL. For example, the common electrode CAT may be a cathode electrode.

An encapsulating layer ENCAP may be disposed on the light-emitting diode layer EDL.

The encapsulating layer ENCAP may have a single-layer structure or a multi-layer structure. For example, as illustrated in FIG. 4, the encapsulating layer ENCAP may include a first encapsulating layer PAS1, a second encapsulating layer PCL, and a third encapsulating layer PAS2.

The first encapsulating layer PAS1 and the third encapsulating layer PAS2 may be inorganic films, and the second encapsulating layer PCL may be an organic film. Among the first encapsulating layer PAS1, the second encapsulating layer PCL, and the third encapsulating layer PAS2, the second encapsulating layer PCL may be the thickest and function as the planarization layer.

The first encapsulating layer PAS1 is disposed on the common electrode CAT. The first encapsulating layer PAS1 may be formed of an inorganic insulating material capable of low-temperature deposition. For example, the first encapsulating layer PAS1 may be silicon nitride (SiNx), silicon oxide (SiOx), silicon oxynitride (SiON), or aluminum oxide (Al₂O₃). Since the first encapsulating layer PAS1 is deposited at a low temperature, the first encapsulating layer PAS1 may suppress the damage of the light-emitting layer EL including an organic material vulnerable to high temperatures during the deposition process.

The second encapsulating layer PCL may be formed with a smaller area than the first encapsulating layer PAS1. In this case, the second encapsulating layer PCL may be formed to expose both ends of the first encapsulating layer PAS1. The second encapsulating layer PCL may act as a buffer to relieve stress between the layers due to bending of the display apparatus 100 and may also act to enhance flattening performance. For example, the second encapsulating layer PCL may be an acrylic resin, an epoxy resin, a polyimide, polyethylene, silicon oxycarbon (SiOC), or the like, and may be formed of an organic insulating material. For example, the second encapsulating layer PCL may be formed using an inkjet method.

For reference, the display panel 50 may have one or more dams at or close to the end of the slope of the encapsulating layer ENCAP to suppress the collapse of the encapsulating layer ENCAP. One or more dams may be at or close to the boundary between the display area DA and the non-display area NA.

The second encapsulating layer PCL including the organic material may be positioned only on the inner surface of the innermost primary dam. That is, the second encapsulating layer PCL may not be present above all the dams. Alternatively, the second encapsulating layer PCL including the organic material may be positioned above at least the primary dam among the primary dam and the secondary dam. That is, the second encapsulating layer PCL may be positioned so as to extend only to an upper portion of the primary dam. Alternatively, the second encapsulating layer PCL may be positioned so as to pass the upper portion of the primary dam to extend to an upper portion of the secondary dam.

The third encapsulating layer PAS2 may be formed on the substrate SUBS on which the second encapsulating layer PCL is formed, to cover the upper surfaces and the side surfaces of the second encapsulating layer PCL and the first encapsulating layer PAS1, respectively. The third encapsulating layer PAS2 minimizes or blocks external moisture or oxygen penetrating into the first encapsulating layer PAS1 and the second encapsulating layer PCL. For example, the third encapsulating layer PAS2 is formed of an inorganic insulating material such as silicon nitride (SiNx), silicon oxide (SiOx), silicon oxynitride (SiON), or aluminum oxide (Al₂O₃).

A touch sensor layer TSL may be disposed on the aforementioned encapsulating layer ENCAP. Hereinafter, the laminated structure of the touch sensor layer TSL will be described.

A touch buffer film T-BUF may be disposed on the encapsulating layer ENCAP, and a touch sensor metal T-SENS may be disposed on the touch buffer film T-BUF. A bridge metal BRG may be disposed on a different layer from the touch sensor metal T-SNES. A touch interlayer insulating layer T-ILD may be disposed between the touch sensor metal T-SENS and the bridge metal BRG.

When forming the touch sensor layer TSL, chemicals (developing solution or etching solution, or the like) used in the process or moisture from the outside may be generated. By disposing the touch buffer film T-BUF and disposing the touch sensor layer TSL thereon, it is possible to suppress the penetration of chemicals or moisture into the light-emitting layer EL containing an organic material during the manufacturing process of the touch sensor layer TSL. Accordingly, the touch buffer film T-BUF may suppress the damage of the light-emitting layer EL which is vulnerable to chemicals or moisture.

The touch buffer film T-BUF may be formed at a low temperature (for example, 100 degrees) or lower in order to suppress the damage of the light-emitting layer EL containing an organic material vulnerable to high temperatures, and is formed of an organic insulating material having a low dielectric constant of 1 to 3. For example, the touch buffer film T-BUF may be formed of an acrylic series, epoxy series, or siloxane series material. Even when the display panel 50 is bent, the touch buffer film T-BUF having flattening performance as an organic insulating material may suppress the damage of the encapsulating layer ENCAP and/or breakage of the metal T-SENS and BRG constituting the touch sensor layer TSL.

A protective layer PAC may be disposed to cover the touch sensor layer TSL. The protective layer PAC may be an organic insulating layer.

A black matrix BM may be disposed on the protective layer PAC. The black matrix BM may include a black-based material. For example, the black matrix BM may include a light-blocking material or a light-absorbing material. For example, the black matrix BM may be composed of a material including a black pigment or a black dye. The black matrix BM may be disposed on the touch sensor layer TSL. This may suppress the recognition of the bridge metal BRG and the touch sensor metal T-SENS from the outside. For example, the width of the black matrix BM may be smaller than the width of the bank BNK.

A color filter CF may be disposed between the black matrices BM. The color filter CF may be composed of a different color for each sub-pixel SP and may block a specific color from light emitted from the light-emitting area of the sub-pixel SP. For example, the color filter CF may be composed of red, green, and blue, and may be disposed on each sub-pixel SP. However, the example implementations of the present disclosure are not limited thereto.

Although not illustrated, the planarization layer may be disposed on the color filter CF. The planarization layer may serve to planarize the step formed by the color filter CF. For example, the planarization layer may include an organic insulating material.

The adhesive member OCA may be disposed on the color filter CF. The adhesive member OCA may include at least any one of a transparent pressure sensitive adhesive (PSA), an optical clear adhesive (OCA), or an optical clear resin (OCR).

A cover glass CG may be disposed on the adhesive member OCA. The cover glass CG may be composed of a glass material including glass or quartz, but the example implementations of the present disclosure are not limited thereto, and may be composed of a plastic material. The cover glass CG may be disposed on the display panel 50 to protect members disposed below the cover glass CG from the outside. The cover glass CG may be a cover glass formed by chemical strengthening, but is not limited thereto. The cover glass CG may be a cover window, a window cover, or a cover member, but is not limited thereto.

Referring to FIG. 4, some of the substrate SUBS and insulating layers BUF, GI, ILD1, ILD2, PLN1, PLN2, BNK, PAS1, PCL, PAS2 and PAC disposed in the non-transparent area NTA may be disposed in the same manner in the transparent area TA.

However, in addition to the insulating material in the non-transparent area NTA, a material layer having electrical properties (for a metal material layer, an active layer, or the like) may not be disposed in the transparent area TA.

For example, the metal material layers GATE, GM, TM, SD1 and SD2 and the active layer ACT related to the transistor are not disposed in the transparent area TA. The light-emitting layer EL may or may not be disposed in the transparent area TA. The touch sensor metal T-SENS and the bridge metal BRG included in the touch sensor layer TSL are not disposed in the transparent area TA.

In addition, in the transparent area TA, a metal patterning layer MPL may be positioned at the position where the common electrode CAT of the non-transparent area NTA is disposed. Accordingly, the transmittance of the transparent area TA may be improved, thereby obtaining improved quality.

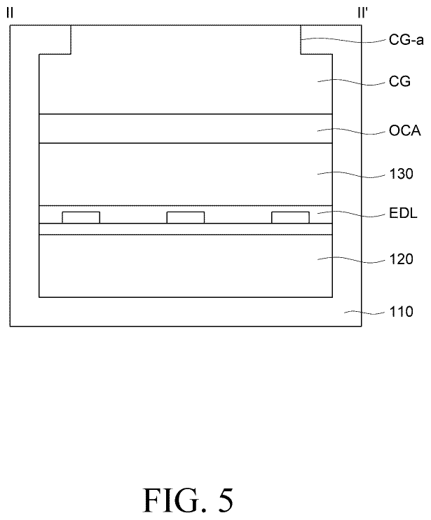

FIG. 5 is a cross-sectional view of the display apparatus according to one example implementation of the present disclosure.

Referring to FIG. 5, a protective film 110 covering the lower portion and the side surface of a first substrate 120 may be disposed. The protective film 110 has a UV blocking function, and thus may solve a problem caused by an oxidation reaction due to short-wave UV light in a high-temperature environment. For example, in the case of the vehicle display, a defect in which discoloration occurs at the edge of the light-emitting portion compared to the central portion may occur due to an increase in exposure time to external UV light. In this case, the protective film 110 covering from the lower portion of the first substrate 120 to a portion of the upper surface of the cover glass CG may block UV light at the side portion, thereby reducing the yellowing phenomenon occurring at the edge. In addition, the display apparatus according to the example implementation of the present disclosure has a structure that can block external light and secure rigidity in a vehicle environment without a polarizing plate or a heat dissipation plate.

In addition, the protective film 110 may be characterized by having a transmittance of 90% or more in the wavelength range of visible light. That is, since the transmittance of the protective film 110 is 90% or more in the wavelength range of blue 470 nm, green 530 nm, and red 625 nm, which are the three primary colors of light, the display apparatus according to the example implementation of the present disclosure may maintain transparency as a transparent display for a vehicle and provide a high-quality display apparatus.

The display apparatus may include the first substrate 120 and a second substrate 130. Referring to FIG. 4, the first substrate 120 may include from the substrate SUBS to the second planarization layer PLN2. The second substrate 130 may include from the encapsulating layer ENCAP to the protective layer PAC. The light-emitting diode layer EDL may be further included between the first substrate 120 and the second substrate 130.

The adhesive member OCA may be fully disposed on the second substrate 130. However, the present disclosure is not limited thereto, and the adhesive member OCA may be partially disposed. The adhesive member OCA may be made of an optically cleared resin (OCR) or an optically cleared adhesive film (OCA Film), but is not limited thereto.

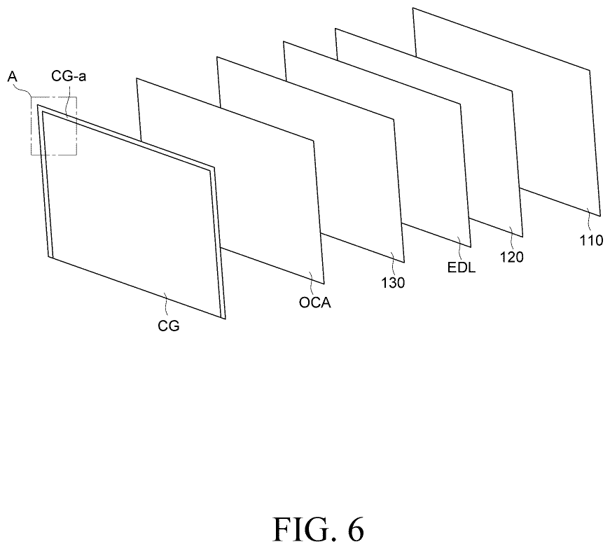

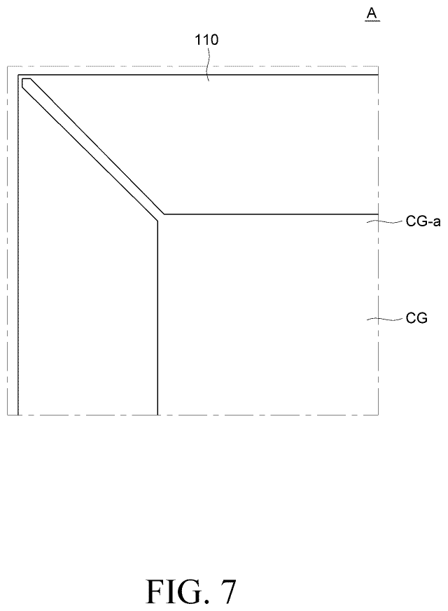

FIG. 6 is an exploded perspective view of the display apparatus according to one example implementation of the present disclosure. FIG. 7 is an enlarged view of an area A of FIG. 6.

Referring to FIG. 6, the display apparatus according to one example implementation of the present disclosure includes a step portion CG-a in a portion of an upper surface of the cover glass CG. The protective film 110 may be formed to have a structure that extends from a lower portion of a substrate SUBS to the step portion CG-a of the upper surface of the cover glass CG and covers the entire area except for the display portion of the display panel 50. The display panel 50 may include the first substrate 120, the light-emitting diode layer EDL, and the second substrate 130, and the adhesive member OCA may be entirely or partially disposed on the second substrate 130. The adhesive member OCA may be made of an optically cleared resin (OCR) or an optically cleared adhesive film (OCA Film), but is not limited thereto.

As illustrated in FIG. 7, the protective film 110 positioned on the step portion CG-a of the cover glass CG may include a cut portion at the corner portion. The cut portion is formed at the corner portion so that it may be attached in a curved form from the rear surface of the substrate SUBS to the front surface through the side surface, and may be attached in a form slightly spaced apart in the diagonal direction from the corner portion. Accordingly, the integrated protective film 110 surrounds the display panel 50, enabling a flat design without overlapping between components, and since the protective film 110 can replace the role of the conventional polarizing plate or heat dissipation plate, a slimmer structure can be enabled. In addition, since the corner including the cut portion is configured in a form that surrounds the cover glass CG, the bonding strength between the components may be strengthened.

The step portion CG-a of the cover glass CG may be positioned on three sides where the COF film COF is not attached. Except for one side where the COF film COF is bent toward the rear surface to connect the cover glass CG and the substrate SUBS, the remaining three sides may be disposed in a form where the three sides are connected through the protective film 110 as an example implementation of the present disclosure. The protective film 110 may include an extension portion to be connected to the step portion CG-a positioned on the upper surface of the cover glass CG. The extension portion may be composed of three, and may be disposed in a trapezoidal shape for each configuration, but is not limited thereto.

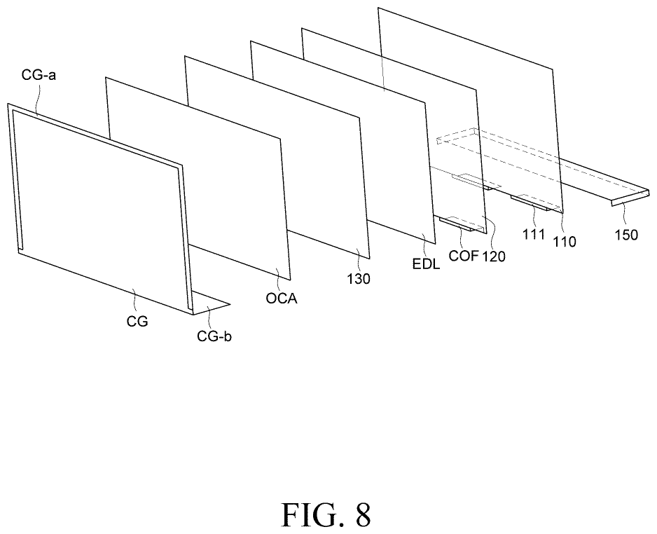

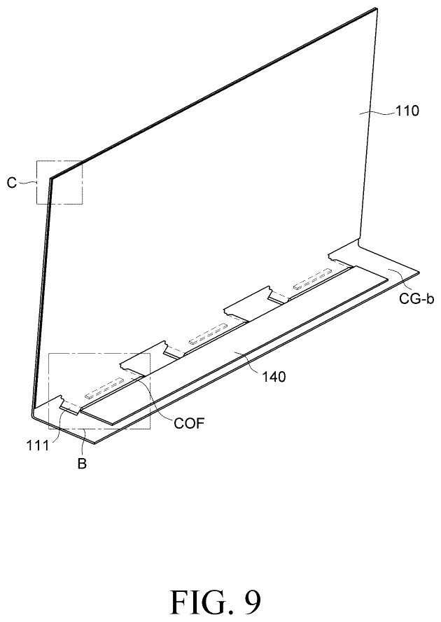

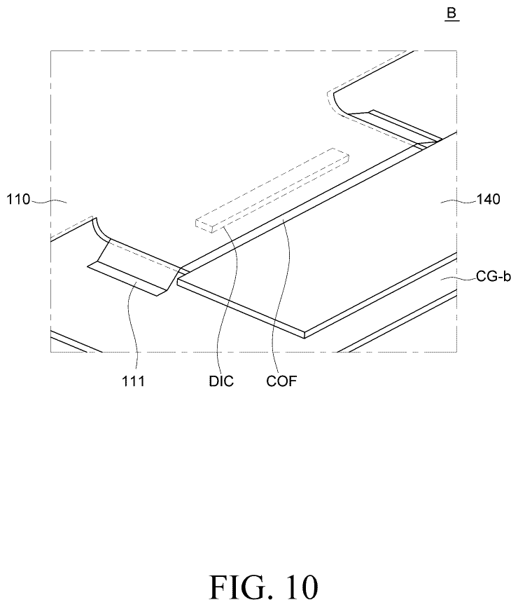

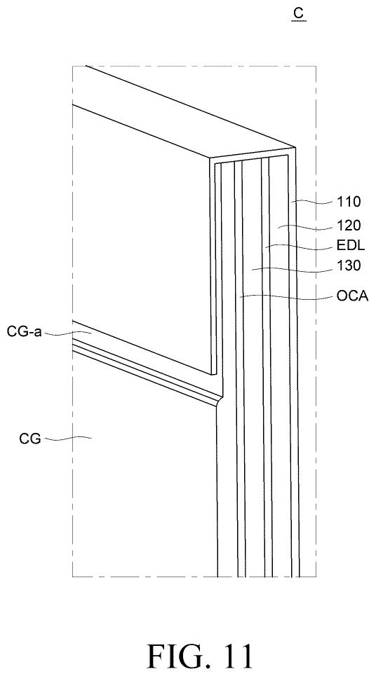

Hereinafter, another example implementation of the present disclosure will be described with reference to FIGS. 8 to 11.

FIGS. 8 to 11 are exploded perspective views of a display apparatus according to another example implementation of the present disclosure.

Referring to FIGS. 8 to 11, in the example implementation of the present disclosure, the cover glass CG may include a bending portion CG-b in addition to the step portion CG-a. The bending portion CG-b may extend toward the rear surface of the cover glass CG and may be positioned to support the printed circuit board 140. The cover glass CG may be made of glass, and may be formed by heat during a molding process. The angle or curvature of the bending portion CG-b may vary depending on the model.

The bending portion CG-b of the cover glass CG may be disposed so that the length in the extension direction is equal to or longer than the lengths of the COF film COF and the printed circuit board 140. Accordingly, even when not fastened with a set frame, movement of components may be suppressed through the bending portion CG-b of the cover glass CG, a slim model can be implemented, and the display that may be coupled to various vehicle structures can be implemented.

According to an example implementation of the present disclosure, the protective film 110 may further include a protrusion 111 that protects the COF film COF and is attached to the bending portion CG-b of the cover glass CG. The protrusion 111 may extend from the protective film 110 and may be disposed as many as the number of COF films COF. For example, when the bending portion CG-b of the cover glass CG is formed at a right angle, the COF film COF and the printed circuit board 140 may be positioned on the bending portion CG-b of the cover glass CG. Moreover, in order to fix the COF film COF, the protrusion 111 of the protective film 110 may surround the COF film COF and both wings of the protrusion 111 may be attached to the cover glass CG. Accordingly, the Driver-IC DIC within the COF film COF may be protected from external impact or contamination. In addition, since the COF film COF attached to one side where the extension portion of the protective film 110 is not positioned can be firmly bonded through the protrusion 111 of the protective film 110, a more robust design can be possible.

According to an example implementation of the present disclosure, a cover portion 150 that surrounds the protrusion 111 of the protective film 110 may be further included. The cover portion 150 may be positioned at a predetermined height so as to be positioned on the COF film COF and the printed circuit board 140. By disposing the cover portion 150, the components described above may be protected without being exposed to external impact or contamination. The cover portion 150 may be positioned to surround the entire area of the bending portion CG-b or may be positioned partially, but is not limited thereto.

Although the disclosure has been described with reference to the above example implementations, it will be understood by those skilled in the art that various modifications and changes can be made to the disclosure without departing from the spirit and scope of the disclosure as set forth in the claims below. In addition, the example implementations disclosed in the present disclosure are not intended to limit the technical idea of the disclosure, and all technical ideas within the scope of the following claims and their equivalents should be interpreted as being included in the scope of the rights of the present disclosure.

The present disclosure relates to a display apparatus including: a display panel including a display portion and a non-display portion; a COF film connected to the non-display portion; a printed circuit board connected to the non-display portion through the COF film; a cover glass positioned on the display panel and including a step portion on at least a portion of an upper surface; and a protective film covering a lower portion and a side surface of the display panel, in which the protective film has a UV blocking function. In addition, transmittance of the protective film may be 90% or more and the protective film may include a first area extending to be positioned on the step portion of the cover glass. The step portion of the cover glass may be positioned in an area where the COF film is not attached, and a plurality of the first areas may be provided and positioned spaced apart from each other. In addition, the display panel of the present disclosure may be a transparent display panel that displays an image and allowing the rear side to be seen through. The display apparatus may further include an adhesive member positioned on the display panel and positioned below the cover glass, and the adhesive member may include a UV blocking function.

The cover glass of the present disclosure may include a bending portion that extends to surround a printed circuit board, and the length of the bending portion in an extension direction thereof may be formed to be equal to or longer than lengths of the COF film and the printed circuit board. The protective film may include one or more second areas extending to be positioned on the COF film, and may include two wing portions that are adhered to the cover glass. In addition, the display apparatus may further include the cover portion covering a rear surface of the second area.

What is claimed is:

1. A display apparatus comprising:
a display panel including a display portion and a non-display portion;
a chip on film (COF) film connected to the non-display portion;
a printed circuit board connected to the non-display portion through the COF film;
a cover glass positioned on the display panel and including a step portion on at least a portion of an upper surface of the cover glass; and
a protective film covering a lower portion and a side surface of the display panel,
wherein the protective film has a UV blocking function.

2. The display apparatus according to claim 1, wherein transmittance of the protective film is 90% or more.

3. The display apparatus according to claim 1, wherein the protective film includes a first area extending to be positioned on the step portion of the cover glass.

4. The display apparatus according to claim 3, the step portion is positioned in an area where the COF film is not attached.

5. The display apparatus according to claim 3, wherein the first area is among a plurality of first areas that are positioned spaced apart from each other.

6. The display apparatus according to claim 3, wherein the first area is among a plurality of first areas that are positioned spaced apart from each other at a corner portion of the cover glass.

7. The display apparatus according to claim 1, wherein the display panel is a transparent display panel that displays an image and allowing the rear side to be seen through.

8. The display apparatus according to claim 1, further comprising an adhesive member positioned on the display panel and positioned below the cover glass.

9. The display apparatus according to claim 8, wherein the adhesive member has a UV blocking function.

10. The display apparatus according to claim 1, wherein the cover glass includes a bending portion extending to surround the printed circuit board.

11. The display apparatus according to claim 10, wherein a length of the bending portion in an extension direction thereof is equal to or longer than lengths of the COF film and the printed circuit board.

12. The display apparatus according to claim 1, wherein the protective film includes one or more second areas extending to be positioned on the COF film.

13. The display apparatus according to claim 12, wherein each of the one or more second areas includes two wing portions bonded to the cover glass.

14. The display apparatus according to claim 12, further comprising a cover portion covering a rear surface of the one or more second areas.

15. The display apparatus according to claim 1, wherein the display apparatus includes the protective film but does not include a polarizing plate and a heat dissipation plate.

16. The display apparatus according to claim 1, wherein the display apparatus is used as a vehicle display.
